(19) United States
(12) Patent Application Publication
(10) Pub. No.: US 2021/0066592 A1
(43) Pub. Date: Mar. 4, 2021

(54) Deposition Of Metal-Organic Oxide Films

(71) Applicant: Applied Materials, Inc., Santa Clara, CA (US)

(72) Inventors: Feng Q. Liu, San Jose, CA (US); Nasrin Kazem, Santa Clara, CA (US); Jeffrey W. Anthis, San Jose, CA (US); Ghazal Saheli, Saratoga, CA (US); David Thompson, San Jose, CA (US)

(73) Assignee: Applied Materials, Inc., Santa Clara, CA (US)

(21) Appl. No.: 17/000,457

(22) Filed: Aug. 24, 2020

Related U.S. Application Data
(60) Provisional application No. 62/891,463, filed on Aug. 26, 2019.

(51) Int. Cl. H01L 45/00; H01L 27/24

(52) U.S. Cl. CPC H01L 45/1616; H01L 27/2463; H01L 45/147

(57) ABSTRACT

Methods of depositing a metal-organic oxide film by exposing a substrate surface to a metal-organic precursor and an oxidant are described. The metal-organic oxide film has the general formula MOₓC_{y}, wherein M comprises one or more of a transition metal, a lanthanide, or a boron group element, x is a whole number in a range of 1 to 6, and y is a number in a range of greater than 0 to 0.5.

### CROSS-REFERENCE TO RELATED APPLICATIONS

This application claims priority to U.S. Provisional Application No. 62/891,463, filed Aug. 26, 2019, the entire disclosure of which is hereby incorporated by reference herein.

### GOVERNMENT LICENSE RIGHTS

This invention was made with U.S. Government support under Agreement No. HR0011-18-3-0008 awarded by Defense Advanced Research Projects Agency. The U.S. Government has certain rights in the invention.

### TECHNICAL FIELD

Embodiments of the present invention pertain to the field of electronic device manufacturing. In particular, embodiments pertain to deposition of metal-organic oxide films with variable and controllable levels of carbon incorporation.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Reducing the size of integrated circuits (ICs) results in improved performance, increased capacity, and/or reduced cost. Each size reduction requires more sophisticated techniques to form the ICs. Shrinking transistor size, for example, allows for the incorporation of an increased number of memory or logic devices on a chip, lending to the fabrication of products with increased capacity. The drive for ever-more capacity, however, is not without issue. The necessity to optimize the performance of each device becomes increasingly significant.

Non-volatile memory is a class of integrated circuits in which the memory cell or element does not lose its state after the power supplied to the device is turned off. The earliest computer memories, made with rings of ferrite that could be magnetized in two directions, were non-volatile. As semiconductor technology evolved into higher levels of miniaturization, the ferrite devices were abandoned for the more commonly known volatile memories, such as DRAM (dynamic random access memories) and SRAMs (static-RAMs). Volatile memory, however, does not meet the needs of all integrated circuits.

Accordingly, there is a need for memory devices that have low power, high speed, and high density with durability.

### SUMMARY

One or more embodiments of the disclosure are directed to a method of depositing a film. In one embodiments, a method of depositing a film comprises: exposing a substrate in a processing chamber to a metal-organic precursor to deposit a metal organic-containing layer; exposing the substrate to an oxidant to react with the metal-organic-containing layer to form a metal-organic oxide film; and purging the processing chamber of the oxidant, wherein the metal-organic oxide film has the general formula MOₓC_{y}, wherein M comprises one or more of a transition metal, a lanthanide, or a boron group element, x is a whole number in a range of 1 to 6, y is a number in a range of greater than 0 to 0.5.

One or more embodiments of the disclosure are directed to a memory material. In one embodiment, a memory material comprises: a metal-organic oxide film on a substrate, the metal-organic oxide film having the general formula MOₓC_{y}, wherein M comprises one or more of a transition metal, a lanthanide, or a boron group element, x is a whole number in a range of 1 to 6, y is a number in a range of greater than 0 to 0.5.

One or more embodiments of the disclosure are directed to a memory cell. In one embodiment, a memory cell comprises: one or more of a top electrode or a bottom electrode; and a metal-organic oxide film having the general formula MOₓC_{y}, wherein M comprises one or more of a transition metal, a lanthanide, or a boron group element, x is a whole number in a range of 1 to 6, y is a number in a range of greater than 0 to 0.5.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow process diagram of a method of forming a metal organic oxide film according to embodiments described herein; and

FIG. 2 depicts an electronic device in accordance with one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. The pretreatment may be in liquid phase or vapor phase. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Conventionally, a metal ALD film is formed by a [A-B]-[C-B] deposition process. Conventionally, a metal oxide layer is formed in a first process cycle comprising sequential exposure of a substrate to a metal precursor, purge gas, first oxidant, and purge gas. A doped metal oxide layer is formed in a second process cycle comprising sequential exposure of the substrate to a dopant precursor, purge gas, second oxidant and purge gas. One or more of the first process cycle or the second process cycle can be repeated to form a film.

A second conventional process involves co-flowing the metal precursor and dopant precursor in an [AC]-[B] process. Specifically, a doped metal oxide layer is formed by exposure of the substrate to both a metal precursor and a dopant precursor, followed sequentially by purge gas, an oxidant, and purge gas.

Chemical vapor deposition (CVD) is another process employed for depositing layers on a substrate. CVD is a flux-dependent deposition technique that requires precise control of the substrate temperature and the precursors introduced into the processing chamber in order to produce a desired layer of uniform thickness.

Embodiments of the present disclosure relate to the deposition of metal-organic oxide films with variable and controllable levels of carbon incorporation. In one or more embodiments, the method of deposition is cyclic and has components of both an ALD process and a CVD process.

As used herein “metal-organic oxide” and “metal-organic oxide film” refer to a film that comprises metal, oxygen, and carbon. In one or more embodiments, the carbon component of the metal-organic oxide film comprises one or more of a carbide, alkenyl, carbonate, or carbonyl. In other embodiments, the carbon component of the metal-organic oxide film comprises one or more of a carbide, alkenyl, or carbonate.

As used herein, the term “carbide” refers to a compound in which carbon is bonded directly to an element which is of lesser electronegativity than carbon (e.g. a transition metal) combine.

As used herein, the term “alkenyl” refers to a linear or branched chain hydrocarbon radical formed by hydrogen and carbon atoms, containing at least one unsaturation, with at least two carbon atoms, and which is joined to the metal-organic oxide film by a bond.

As used herein, the term “carbonate” refers to an organic compound containing a carbonate group,

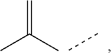

and joined to the metal-organic oxide film by a bond.

As used herein, the term “carbonyl” refers to an organic compound containing a carbonyl group,

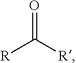

and joined to the metal-organic oxide film by a bond, include carbon monoxide (CO).

In one or more embodiments, the metal-organic oxide film contains greater than 0% carbon to greater than about 50% carbon (C) on an atomic basis, including greater than about 1%, greater than about 5%, greater than about 10%, greater than about 15%, greater than about 20%, greater than about 25%, greater than about 30%, greater than about 35%, greater than about 40%, greater than about 45%, or greater than about 50%. In one or more embodiments, the metal-organic oxide film contains less than about 50% total metal content on an atomic basis, including less than about 45% total metal, less than about 40% total metal, less than about 35% total metal, or less than about 30% total metal. In other embodiments, the metal-organic oxide film contains less than about 90% total metal content on an atomic basis, including less than about 85% total metal, less than about 80% total metal, less than about 75% total metal, less than about 70% total metal, less than about 65% total metal, less than about 60% total metal, less than about 55% total metal, less than about 50% total metal, less than about 40% total metal, less than about 35% total metal, or less than about 30% total metal. As used herein, the term “total metal content” refers to the percentage of metal, on an atomic basis, present in the metal-organic oxide film. The metal may come from the metal-organic precursor, the reactant, and additional precursors, if present.

In one or more embodiments, incorporating a metal-organic oxide film with variable and controllable levels of carbon incorporation in a memory device, e.g. a non-volatile memory to tune a film's electronic function in the memory device, or as a barrier layer in a logic device.

In one or more embodiments, the metal-organic oxide film has the general formula MOₓC_{y}, wherein M comprises one or more of a transition metal, a lanthanide, or a boron group element, x is a whole number in a range of 1 to 6, y is a number in a range of greater than 0 to 0.5.

In one or more embodiments, the transition metal comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), or mercury (Hg). In one or more embodiments, the lanthanide comprises one or more of lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), or lutetium (Lu). In one or more embodiments, the boron group metal comprises one or more of boron (B), aluminum (Al), gallium (Ga), indium (In), or thallium (TI).

Accordingly, in some embodiments, the metal M comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), lutetium (Lu, boron (B), aluminum (Al), gallium (Ga), indium (In), or thallium (TI). In one or more specific embodiments, the metal M comprises one or more of nickel (Ni), hafnium (Hf), yttrium (Y), or zirconium (Zr).

In one or more embodiments, x is a whole number in a range of 1 to 6. Thus, in one or more embodiments, the metal-organic oxide comprises 1, 2, 3, 4, 5, or 6 oxygen atoms.

In one or more embodiments, the metal-organic oxide film comprises one or more of a carbide, alkenyl, carbonate, or carbonyl. In one or more embodiments, y is a number in a range of greater than 0 to about 0.5. In some embodiments y is about 0.00001 to about 0.5, including about 0.0001, about 0.00025, about 0.0005, about 0.00075, about 0.001, about 0.0025, about 0.005, about 0.0075, about 0.01, about 0.025, about 0.05, about 0.075, about 0.1, about 0.25, or about 0.5.

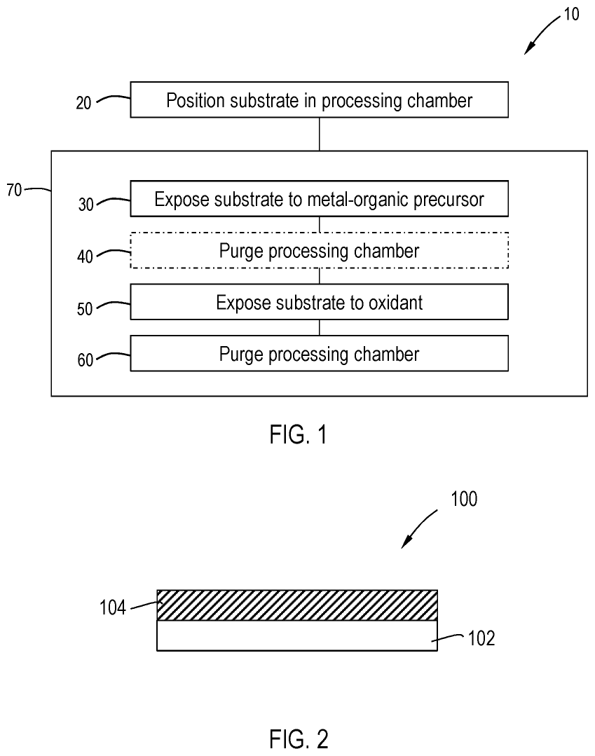

FIG. 1 depicts a flow diagram of a method 10 of depositing a metal-organic oxide film in accordance with one or more embodiments of the present disclosure. With reference to FIG. 1, the method 10 comprises a deposition cycle 70. The method 10 begins at operation 20 by positioning a substrate into a processing chamber.

At operation 30, at least a portion of the substrate surface is exposed to a metal-organic precursor. In one or more embodiments, the metal-organic precursor comprises one or more amide based metal-organic precursor including, but not limited to, precursors having the general formula, RₐML_{b}, wherein L can be equal R; M is a metal comprising one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), lutetium (Lu, boron (B), aluminum (Al), gallium (Ga), indium (In), or thallium (TI). The subscript “a” is a number from 0 to 3, including 0, 1, 2, or 3, and b is a number from 0 to 3, including, 1, 2, or 3. R comprises one or more of cyclopentadienyl, methyl cyclopentadienyl, ethyl cyclopentadienyl, or isopropyl cyclopentadienyl. L comprises one or more of amino derivatives R′R″N, amidinate derivative R′NR″CNR′, or R′O, wherein is R′ comprises methyl, ethyl, propyl, isopropyl, or t-butyl; R″ comprises methyl, ethyl, propyl, or isopropyl.

In one or more embodiments, the precursor comprises one or more of Tetrakis(dimethylamido) zirconium, Tetrakis(ethylmethylamido) zirconium, Zirconium(IV) t-butoxide, Bis(cyclopentadienyl) nickel, Bis(ethylcyclopentadienyl) nickel, Bis(i-propylcyclopentadienyl) nickel, Tris(N,N′-di-i-propylformamidinato) yttrium, Tris(methylcyclopentadienyl) yttrium, Tris(n-propylcyclopentadienyl) yttrium, Bis(cyclopentadienyl)(N,N′-di-i-propylformamidinato) yttrium, (Cyclopentadienyl)tris(ethylmethylamido) zirconium, (Cyclopentadienyl)tris(ethylmethylamido) hafnium, or (Ethyl Cyclopentadienyl)tris(ethylmethylamido) zirconium.

In one or more embodiments, the metal-organic precursor-containing process gas is provided in one or more pulses. In other embodiments, the metal-organic precursor-containing process gas is provided continuously. In one or more embodiments, the flow rate of the metal-organic precursor-containing process gas is any suitable flow rate including, but not limited to, flow rates in the range of about 1 to about 5000 sccm, or in the range of about 50 to about 4000 sccm, or in the range of about 100 to about 3000 sccm or in the range of about 200 to about 2000 sccm. In one or more embodiments, the metal-organic precursor is provided at any suitable pressure including, but not limited to, a pressure in the range of about 0.005 Torr to about 30 Torr, or in the range of about 0.1 Torr to about 30 Torr, or in the range of about 0.5 Torr to about 10 Torr.

In one or more embodiments, the period of time that the substrate is exposed to the metal-organic precursor-containing process gas is any suitable amount of time necessary to allow the precursor to form an adequate nucleation layer atop the substrate surfaces. For example, in one or more embodiments, the process gas is flowed into the process chamber for a period of about 0.1 seconds to about 90 seconds. In one or more embodiments, in some time-domain ALD processes, the metal-organic precursor-containing process gas is exposed the substrate surface for a time in the range of about 0.1 sec to about 90 sec, or in the range of about 0.5 sec to about 60 sec, or in the range of about 1 sec to about 30 sec, or in the range of about 0.2 sec to about 20 sec, or in the range of about 0.2 sec to about 10 sec.

In some embodiments, an inert carrier gas may additionally be provided to the process chamber at the same time as the metal-organic precursor-containing process gas. The carrier gas may be mixed with the metal-organic precursor-containing process gas (e.g., as a diluent gas) or separately and can be pulsed or of a constant flow. In some embodiments, the carrier gas is flowed into the processing chamber at a constant flow in the range of about 1 to about 10000 sccm. The carrier gas may be any inert gas, for example, such as argon, nitrogen, helium, neon, combinations thereof, or the like. In one or more specific embodiments, the metal-organic precursor-containing process gas is mixed with argon prior to flowing into the process chamber.

In one or more embodiments, the temperature of the substrate during deposition can be controlled, for example, by setting the temperature of the substrate support or susceptor. In some embodiments the substrate is held at a temperature in a range of about 100° C. to about 500° C., including a temperature of about 100° C., about 150° C., about 200° C., about 250°, about 300° C., about 350° C., about 400° C., about 450° C., and about 500° C.

At operation 40, the processing chamber is optionally purged of the metal-organic precursor. In some embodiments, the processing chamber is partially purged of the metal-organic precursor, such that some of the metal-organic precursor remains.

In conventional ALD or CVD deposition of metal oxides, the system is saturated (or over dosed) with an oxygen source (O₂, O₃, O₂ plasma, water, etc.). Typically, this saturation leads to fully stoichiometric metal oxides with the hydrocarbon fragment of the organometallic precursor being completely combusted and pumped away as CO₂.

Without intending to be bound by theory, it is thought that by lowering the dose of the oxidant source to a point where is it sub-saturated with respect to the organometallic precursor there is partial oxidation of the organic ligands leaving carbon in the resulting film. In one or more embodiments, by controlling the level of sub-saturation, the carbon concentration in the film is controlled and varied.

In one or more embodiments, an ALD process for the generation of a saturated metal oxide film is developed. In the process of exploring the ALD process, space and saturation curves are generated for oxygen dosing. In one or more embodiments, process conditions are taken from the sub-saturated region of the curve, and metal-organic oxides films with some level of carbon are obtained. In one or more embodiments, the level of carbon in the metal-organic oxide film is calibrated to the oxygen dose.

At operation 50, at least a portion of the substrate surface is exposed to an oxidant to deposit a metal-organic oxide film. In one or more embodiments, the oxidant is selected from one or more of H₂O, molecular oxygen (O₂), ozone (O₃), direct O₂ plasma, or remote O₂ plasma.

At operation 60, the processing chamber is then purged of the oxidant, and the metal-organic oxide film is deposited on the substrate surface.

In one or more embodiments, the cycle 70 can be repeated one or more times to produce a metal-organic oxide film having a thickness in a range of about 2 nm to about 200 nm.

In some embodiments, exposing the substrate surface to the metal-organic precursor and the oxidant occurs sequentially. For example, an ALD type process so that the substrate surface (or portion thereof) is exposed to the metal-organic precursor and the oxidant sequentially or substantially sequentially. In some embodiments, exposing the substrate surface to the metal-organic precursor and the oxidant occurs simultaneously. For example, a CVD type process in which both the metal-organic precursor and the oxidant are flowed into the processing chamber at the same time, allowing gas phase reactions of the precursor and the reactant.

In one or more embodiments, metal-organic oxide films having the general formula MOₓC_{y} can function as ReRAM or CeRAM devices.

As used herein, the term “ReRAM” or “RRAM” refers to resistive random-access memory, which is a type of non-volatile (NV) random-access (RAM) computer memory that works by changing the resistance across a dielectric solid-state material, often referred to as a memristor.

As used herein, the term “CEM” or “correlated electron material” refers to materials that exhibit an abrupt conductor/insulator transition due to electron correlations rather than solid state structural phase changes, i.e., crystalline/amorphous or filamentary phase changes. Embodiments described herein include CeRAM switches and memories. They are referred to as “CeRAM” based on the strong electron correlation observed in such materials, and, in particular, a metal-insulator-metal (MIM) structure formed with Pt/NiO/Pt, i.e., as a layer including nickel oxide (NiO) between platinum (Pt) electrodes.

Although resistance switching properties have been observed in a variety of materials, in the embodiments described herein, metal-organic oxide films having the general formula MOₓC_{y}, have advantages due to their uni-directional programmability for simplified cross-point array structures.

One or more embodiments of the disclosure are directed to a memory material. With reference to FIG. 2, in one or more embodiments, the memory material 100 comprises a metal-organic oxide film 104 on a substrate 102. The metal-organic oxide film 104 is formed on the substrate 102, which can be any suitable material or shape. In the embodiment illustrated, the substrate 102 is a flat surface and the metal-organic oxide film 104 is represented by a rectangular box placed on top of the substrate 102. However, those skilled in the art will understand that the substrate 102 can have one or more features (i.e., trenches, vias, or the like), and that the metal-organic oxide film can be formed to conform to the shape of the substrate 201 surface.

In one or more embodiments, the metal-organic oxide film 104 has the general formula MOₓC_{y}, wherein M comprises one or more of a transition metal, a lanthanide, or a boron group element, x is a whole number in a range of 1 to 6, and y is a number in a range of greater than 0 to 0.5.

In one or more embodiments, the transition metal comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), or mercury (Hg). In one or more embodiments, the lanthanide comprises one or more of lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), or lutetium (Lu). In one or more embodiments, the boron group metal comprises one or more of boron (B), aluminum (Al), gallium (Ga), indium (In), or thallium (TI).

Accordingly, in some embodiments, the metal M comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), lutetium (Lu, boron (B), aluminum (Al), gallium (Ga), indium (In), or thallium (TI). In one or more specific embodiments, the metal M comprises one or more of nickel (Ni), hafnium (Hf), yttrium (Y), or zirconium (Zr).

In one or more embodiments, x is a whole number in a range of 1 to 6. Thus, in one or more embodiments, the metal-organic oxide film 104 comprises 1, 2, 3, 4, 5, or 6 oxygen atoms.

In one or more embodiments, the metal-organic oxide film 104 comprises one or more of a carbide, alkenyl, carbonate, or carbonyl. In one or more embodiments, y is a number in a range of greater than 0 to about 0.5. In some embodiments y is about 0.00001 to about 0.5, including about 0.0001, about 0.00025, about 0.0005, about 0.00075, about 0.001, about 0.0025, about 0.005, about 0.0075, about 0.01, about 0.025, about 0.05, about 0.075, about 0.1, about 0.25, or about 0.5.

In one or more embodiments, the metal-organic oxide film 104 is part of one or more of a correlated electron memory (CeRAM) device or a resistive memory (ReRAM) device. In some embodiments, the metal-organic oxide film 104 is integrated into one or more of the top electrode or the bottom electrode of a ReRAM device. In other embodiments, the metal-organic oxide film 104 is integrated into one or more of the top electrode or the bottom electrode of a CeRAM device.

In one or more embodiments, a correlated electron memory device comprises the memory material 100. In one or more additional embodiments, a resistive memory device comprises the memory material 100.

One or more embodiments of the disclosure are directed to a memory cell. In one or more embodiments, a memory cell comprises one or more of a top electrode or a bottom electrode; and a metal-organic oxide film having the general formula MOₓC_{y}, wherein M comprises one or more of a transition metal, a lanthanide, or a boron group element, x is a whole number in a range of 1 to 6, and y is a number in a range of greater than 0 to 0.5. In one or more embodiments, the metal-organic oxide film in the memory cell comprises one or more of a carbide, alkenyl, carbonate, or carbonyl.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a film, the method comprising:
exposing a substrate in a processing chamber to a metal-organic precursor to deposit a metal organic-containing layer;
exposing the substrate to an oxidant to react with the metal organic-containing layer to form a metal-organic oxide film; and
purging the processing chamber of the oxidant,
wherein the metal-organic oxide film has a general formula MOₓC_{y}, wherein M comprises one or more of a transition metal, a lanthanide, or a boron group element, x is a whole number in a range of 1 to 6, y is a number in a range of greater than 0 to 0.5.

2. The method of claim 1, further comprising purging the processing chamber of the metal-organic precursor prior to exposing the substrate to the oxidant.

3. The method of claim 1, wherein the transition metal comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), or mercury (Hg).

4. The method claim 1, wherein the lanthanide comprises one or more of lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), or lutetium (Lu).

5. The method of claim 1, wherein the boron group element comprises one or more of boron (B), aluminum (Al), gallium (Ga), indium (In), or thallium (TI).

6. The method of claim 1, wherein M comprises one or more of nickel (Ni), hafnium (Hf), yttrium (Y), or zirconium (Zr).

7. The method of claim 1, wherein the metal-organic oxide film comprises one or more of carbide, carbonate, alkenyl, and carbonyl.

8. The method of claim 1, wherein purging the processing chamber comprises flowing a purge gas over the substrate.

9. The method of claim 8, wherein the purge gas is selected from one or more of Ar, N₂, or He.

10. The method of claim 1, wherein the oxidant comprises one or more of H₂O, molecular oxygen (O₂), ozone (O₃), direct O₂ plasma, or remote O₂ plasma.

11. A memory material comprising:
a metal-organic oxide film on a substrate, the metal-organic oxide film having a general formula MOₓC_{y}, wherein M comprises one or more of a transition metal, a lanthanide, or a boron group element, x is a whole number in a range of 1 to 6, y is a number in a range of greater than 0 to 0.5.

12. The memory material of claim 11, wherein the transition metal comprises one or more of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), or mercury (Hg).

13. The memory material of claim 11, wherein the lanthanide comprises one or more of lanthanum (La), cerium (Ce), praseodymium (Pr), neodymium (Nd), promethium (Pm), samarium (Sm), europium (Eu), gadolinium (Gd), terbium (Tb), dysprosium (Dy) holmium (Ho), erbium (Er), thulium (Tm), ytterbium (Yb), or lutetium (Lu).

14. The memory material of claim 11, wherein the boron group element comprises one or more of boron (B), aluminum (Al), gallium (Ga), indium (In), or thallium (TI).

15. The memory material of claim 11, wherein M comprises one or more of nickel (Ni), hafnium (Hf), yttrium (Y), or zirconium (Zr).

16. The memory material of claim 11, wherein the metal-organic oxide film comprises one or more of carbide, carbonate, alkenyl, and carbonyl.

17. The memory material of claim 11, wherein the metal-organic oxide film is part of one or more of a correlated electron memory (CeRAM) device or a resistive memory (ReRAM) device.

18. A memory cell comprising:
one or more of a top electrode or a bottom electrode; and
a metal-organic oxide film having a general formula MOₓC_{y}, wherein M comprises one or more of a transition metal, a lanthanide, or a boron group element, x is a whole number in a range of 1 to 6, y is a number in a range of greater than 0 to 0.5.

19. The memory cell of claim 18, wherein the metal-organic oxide film comprises one or more of carbide, carbonate, alkenyl, and carbonyl.

20. A correlated electron memory device comprising the memory material of claim 11.
